(19) United States
(12) Patent Application Publication
(10) Pub. No.: US 2026/0362896 A1
(43) Pub. Date: Nov. 12, 2026

(54) Display Device And Electronic Device Including The Same

(71) Applicant: Samsung Display Co., Ltd., Yongin-si (KR)

(72) Inventors: Eunah Kim, Yongin-si (KR); Sanghwan Park, Yongin-si (KR)

(73) Assignee: Samsung Display Co., Ltd., Yongin-si (KR)

(21) Appl. No.: 19/638,270

(22) Filed: Apr. 3, 2026

(30) Foreign Application Priority Data
May 7, 2025 (KR) 10-2025-0058877

(51) Int. Cl. H10K 50/19; H10K 59/122; H10K 102/00

(52) U.S. Cl. CPC H10K 50/19; H10K 59/122; H10K 2102/351

(57) ABSTRACT

Provided is a display device including a substrate, a thin-film transistor arranged on the substrate, a planarization layer covering the thin-film transistor, a first emission element electrically connected to the thin-film transistor and including a first pixel electrode, a first lower emission layer, a first intermediate electrode, a first upper emission layer, and a counter electrode sequentially stacked on the planarization layer, and a pixel defining layer located on the planarization layer and covering an edge of the first pixel electrode to define an emission area of the first emission element, wherein, in a stacking direction of the first pixel electrode, the first lower emission layer, and the first intermediate electrode, a first contact area where the first pixel electrode and the first lower emission layer are in contact with each other is located in a second contact area where the first intermediate electrode and the first lower emission layer are in contact with each other.

### CROSS-REFERENCE TO RELATED APPLICATION

This application is based on and claims priority under 35 USC § 119 to Korean Patent Application No. 10-2025-0058877, filed on May 7, 2025, in the Korean Intellectual Property Office, the disclosure of which is incorporated by reference herein in its entirety.

### TECHNICAL FIELD

One or more aspects relate to a display device and an electronic device including the same.

### BACKGROUND

As the information society evolves, the demand for display devices to display images is increasing in various forms. For example, display devices are applied to various electronic devices, such as smartphones, digital cameras, notebook computers, navigation devices, and smart televisions. A display device may include an emission element which emits light by itself, thereby displaying images even without a backlight unit which emits light to a display panel.

The above-described information disclosed in the background technology of this disclosure is only intended to improve understanding of the background of the disclosure and therefore may include information that does not constitute the prior art.

### SUMMARY

One or more aspects provide a display device with improved reliability and an electronic device including the same.

However, aspects of the disclosure are not restricted to the one set forth herein, and the other aspects of the disclosure will become more apparent to those skilled in the art to which the disclosure pertains by referencing the following detailed description of the disclosure.

According to one or more aspects, a display device includes a substrate, a thin-film transistor arranged on the substrate, a planarization layer covering the thin-film transistor, a first emission element electrically connected to the thin-film transistor and including a first pixel electrode, a first lower emission layer, a first intermediate electrode, a first upper emission layer, and a counter electrode sequentially stacked on the planarization layer, and a pixel defining layer located on the planarization layer and covering an edge of the first pixel electrode to define an emission area of the first emission element, wherein, in the plan view, the first lower emission layer has an plan view area, and in the plan view, the emission area of the first emission element is located in the plan view area of the first lower emission layer.

In an aspect, the first intermediate electrode may include a first bottom charge generation layer, a first top charge generation layer, and a first metal layer between the first bottom charge generation layer and the first top charge generation layer.

In an aspect, a thickness of the first metal layer may be in a range of 0.1 nm to 10 nm.

In an aspect, the display device may further include a second emission element electrically connected to the thin-film transistor and including a second pixel electrode, a second lower emission layer, a second intermediate electrode, a second upper emission layer, and the counter electrode sequentially stacked on the planarization layer, the second intermediate electrode may include a second bottom charge generation layer, a second top charge generation layer, and a second metal layer between the second bottom charge generation layer and the second top charge generation layer, and the first metal layer and the second metal layer may each have an island shape by being spaced apart from each other.

In an aspect, the first bottom charge generation layer and the second bottom charge generation layer may be integral with each other.

In an aspect, the first top charge generation layer and the second top charge generation layer may be integral with each other.

In an aspect, the first emission element and the second emission element may be arranged adjacent to each other, and the first metal layer and the second metal layer may be integral with each other.

In an aspect, a thickness of the first lower emission layer may be different from a thickness of the second lower emission layer and a thickness of the first upper emission layer may be different from a thickness of the second upper emission layer.

In an aspect, the first emission element may further include a first lower step compensation layer located between the first pixel electrode and the first lower emission layer, and the second emission element may further include a second lower step compensation layer located between the second pixel electrode and the second lower emission layer and having a different thickness from the first lower step compensation layer.

In an aspect, the first emission element may further include a first upper step compensation layer located between the first intermediate electrode and the first upper emission layer, and the second emission element may further include a second upper step compensation layer located between the second intermediate electrode and the second upper emission layer and having a different thickness from the first upper step compensation layer.

According to one or more aspects, a display device includes a substrate, a thin-film transistor arranged on the substrate, a planarization layer covering the thin-film transistor, a first emission element electrically connected to the thin-film transistor and including a first pixel electrode, a first lower emission layer, a first intermediate electrode, a first upper emission layer, and a counter electrode sequentially stacked on the planarization layer, and a second emission element electrically connected to the thin-film transistor and including a second pixel electrode, a second lower emission layer, a second intermediate electrode, a second upper emission layer, and the counter electrode sequentially stacked on the planarization layer, the first intermediate electrode includes a first bottom charge generation layer, a first top charge generation layer, and a first metal layer between the first bottom charge generation layer and the first top charge generation layer, the second intermediate electrode includes a second bottom charge generation layer, a second top charge generation layer, and a second metal layer between the second bottom charge generation layer and the second top charge generation layer, and the first metal layer and the second metal layer each have an island shape by being spaced apart from each other.

In an aspect, a thickness of the first metal layer and a thickness of the second metal layer may be in a range of 0.1 nm to 10 nm.

In an aspect, the display device may further include a pixel defining layer located on the planarization layer and defining an emission area of the first emission element by covering an edge of the first pixel electrode and an emission area of the second emission element by covering an edge of the second pixel electrode, and in the plan view, the first lower emission layer has an plan view area, and in the plan view, the emission area of the first emission element is located in the plan view area of the first lower emission layer.

In an aspect, the first bottom charge generation layer and the second bottom charge generation layer may be integral with each other.

In an aspect, the first top charge generation layer and the second top charge generation layer may be integral with each other.

In an aspect, the first emission element and the second emission element may be arranged adjacent to each other, and the first metal layer and the second metal layer may be integral with each other.

In an aspect, a thickness of the first lower emission layer may be different from a thickness of the second lower emission layer and a thickness of the first upper emission layer may be different from a thickness of the second upper emission layer.

In an aspect, the first emission element may further include a first lower step compensation layer located between the first pixel electrode and the first lower emission layer, and the second emission element may further include a second lower step compensation layer located between the second pixel electrode and the second lower emission layer and having a different thickness from the first lower step compensation layer.

In an aspect, the first emission element may further include a first upper step compensation layer located between the first intermediate electrode and the first upper emission layer, and the second emission element may further include a second upper step compensation layer located between the second intermediate electrode and the second upper emission layer and having a different thickness from the first upper step compensation layer.

According to one or more aspects, an electronic device includes a display device, and the display device includes a substrate, a thin-film transistor arranged on the substrate, a planarization layer covering the thin-film transistor, a first emission element electrically connected to the thin-film transistor and including a first pixel electrode, a first lower emission layer, a first intermediate electrode, a first upper emission layer, and a counter electrode sequentially stacked on the planarization layer, and a pixel defining layer located on the planarization layer and covering an edge of the first pixel electrode to define an emission area of the first emission element, wherein, in the plan view, the first lower emission layer has an plan view area, and in the plan view, the emission area of the first emission element is located in the plan view area of the first lower emission layer.

### BRIEF DESCRIPTION OF THE DRAWINGS

The following drawings attached to this specification illustrate preferred aspects of the disclosure and, together with the detailed description of the disclosure described below, serve to further understand the technical idea of the disclosure; therefore, the disclosure should not be interpreted as being limited to matters described in such drawings:

FIG. 1 is a schematic perspective view of a display device according to an aspect;

FIG. 2 is a schematic cross-sectional view of a cross-section taken along line I-I′ of the display device of FIG. 1;

FIG. 3 is a schematic plane view of a display panel according to an aspect;

FIGS. 4 and 5 are brief views of equivalent circuits of a pixel included in a display panel according to an aspect;

FIG. 6 is a schematic cross-sectional view of an example of a cross-section taken along line II-II′ of FIG. 3;

FIG. 7 is a schematic cross-sectional view of an emission element according to an aspect;

FIG. 8 is a schematic cross-sectional view of an emission element according to another aspect;

FIG. 9 is a schematic cross-sectional view of two adjacent emission elements according to an aspect;

FIG. 10 is a schematic cross-sectional view of layers of the emission elements shown in FIG. 9;

FIG. 11 is a schematic cross-sectional view of two adjacent emission elements according to another aspect;

FIG. 12 is a block diagram of an electronic device according to aspect; and

FIG. 13 is a variety of schematic views of an electronic device according to various aspects.

### DETAILED DESCRIPTION

As the disclosure allows for various changes and numerous aspects, certain aspects will be illustrated in the drawings and described in detail in the written description. Effects and features of the disclosure, and methods of achieving them will be clarified with reference to aspects described below in detail with reference to the drawings. The disclosure may, however, be embodied in many different forms and should not be construed as being limited to the aspects set forth herein.

In the following aspects, while such terms as “first,” “second,” etc., may be used to describe various elements, such elements must not be limited to the above terms.

The singular forms as used herein are intended to include the plural forms as well unless the context clearly indicates otherwise.

It will be further understood that the terms “include” and/or “comprise” used herein specify the presence of stated features or elements, but do not preclude the presence or addition of one or more other features or elements.

In the aspects disclosed below, in case that a part, such as a unit, area, or element, is said to be located on another part, it will include not only the case where the part is directly located on the another part, but also the case where other intervening units, areas, or elements are present.

In the following aspects, terms such as connect or couple do not necessarily mean a direct and/or fixed connection or coupling of two members, unless the context clearly indicates otherwise, and do not exclude the case where another member is interposed between the two members.

Sizes of elements in the drawings may be exaggerated for convenience of explanation. For example, since sizes and thicknesses of elements in the drawings are arbitrarily illustrated for convenience of explanation, the following aspects are not limited thereto.

The disclosure will now be described more fully with reference to the accompanying drawings, in which preferred aspects of the disclosure are shown. In description with reference to the drawings, the same or like elements will be given the same reference numeral, and a redundant description will be omitted.

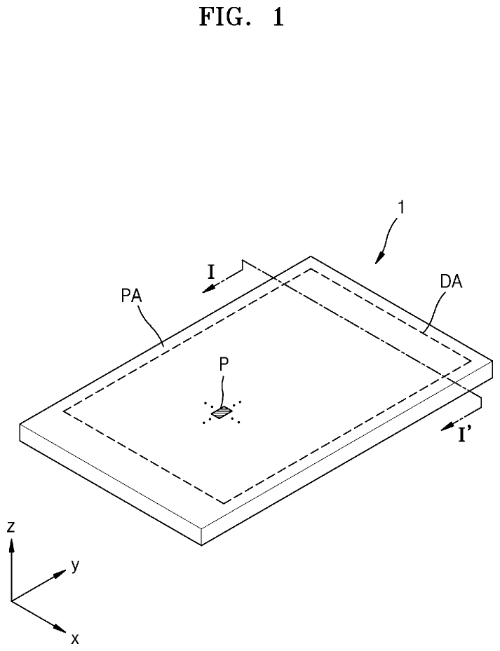

FIG. 1 is a schematic perspective view of a display device according to an aspect.

A display device 1 may be a device which displays moving images or still images, and may be used as a display screen of various electronic devices, such as televisions, laptops, monitors, billboards, and Internet of things (IoT) devices, as well as portable electronic devices, such as mobile phones, smartphones, tablet personal computers (PCs), mobile communication terminals, electronic organizers, e-books, portable multimedia players (PMPs), navigation devices, and ultra mobile PCs (UMPCs). The display device 1 according to an aspect may also be applied to wearable devices, such as smart watches, watch phones, glasses-type displays, and head mounted displays (HMDs). The display device 1 according to an aspect may also be used in dashboards of automobiles, center information displays (CIDs) on the center fascia or dashboards of automobiles, room mirror displays replacing side mirrors of automobiles, and display screens on the rear sides of front seats to serve as entertainment devices for backseat passengers of automobiles. The display device 1 may be bendable, foldable, or rollable. For convenience of explanation, FIG. 1 shows that a display device 1 according to an aspect is used as a smart phone.

The display device 1 may have a rectangular shape on a plane. For example, the display device 1 may have a rectangular planar shape having short sides in an x-axis direction and long sides in a y-axis direction, as shown in FIG. 1. A corner where the short side in the x-axis direction and the long side in the y-axis direction meet may be rounded to have a certain curvature or formed at a right angle. The planar shape of the display device 1 is not limited to the rectangle, and may be formed in other polygonal, elliptical, or irregular shapes.

The display device 1 may include a display area DA which is an area where an image is displayed, and a peripheral area PA surrounding the outside of the display area DA. The peripheral area PA may be an area where pixels P are not arranged and thus an image is not displayed. For example, the peripheral area PA may be a dead space.

In a plan view as shown herein, “left”, “right”, “up”, and “down” may indicate directions when viewing the display device 1 from a direction perpendicular to the display device 1. For example, “left” may indicate a −x direction, “right” may indicate a +x direction, “up” may indicate +y direction, and “down” may indicate a −y direction.

The display area DA may be a portion where images are displayed, and a plurality of pixels P may be arranged in the display area DA. Each of the pixels P may denote a sub-pixel, and may include a display element, such as a light-emitting diode. The display element may be arranged on a substrate 100 in the display area DA. The pixel P may emit, for example, red light, green light, blue light, or white light.

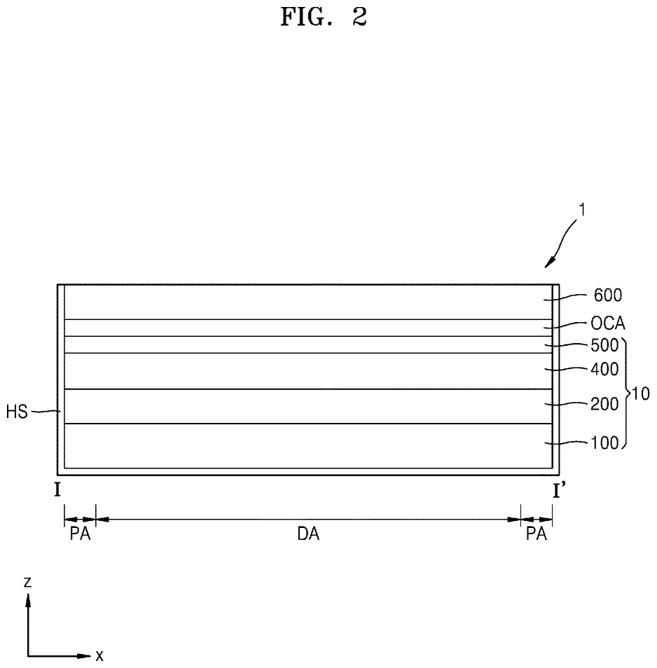

FIG. 2 is a schematic cross-sectional view of a cross-section taken along line I-I′ of the display device of FIG. 1.

Referring to FIG. 2, the display device 1 may include a display panel 10 and a housing HS which accommodates the display panel 10.

The display panel 10 may include a substrate 100, a display layer 200, an input sensing layer 400, an optical function layer 500, and a cover window 600.

The display layer 200 may include display elements (or light-emitting diodes) which emit light to display an image, and pixel circuits which are connected to the display elements, respectively, and apply electrical signals to the corresponding display elements. Each of the display elements may include a light-emitting diode, for example, an organic light-emitting diode including an organic emission layer.

The input sensing layer 400 may obtain coordinate information according to an external input, for example, a touch event. The input sensing layer 400 may include sensing electrodes (or touch electrodes) and trace lines connected to the sensing electrodes. The input sensing layer 400 may be arranged on the display layer 200. The input sensing layer 400 may sense an external input by a mutual-capacitance method or/and a self-capacitance method.

The input sensing layer 400 may be formed directly on the display layer 200, or may be formed separately and then coupled to the display layer 200 by an adhesive layer, such as an optical clear adhesive (OCA). For example, a process of forming the input sensing layer 400 may be performed continuously after a process of forming the display layer 200, and in this case, the adhesive layer may not be arranged between the input sensing layer 400 and the display layer 200. Although FIG. 2 shows that the input sensing layer 400 is arranged between the display layer 200 and the optical function layer 500, as another aspect, the input sensing layer 400 may be arranged on the optical function layer 500.

The optical function layer 500 may include an anti-reflection layer. The anti-reflection layer may reduce the reflectance of light (external light) which is incident from the outside toward the display panel 10 through the cover window 600. The anti-reflection layer may include a phase retarder and a polarizer. The phase retarder may be of a film type or a liquid crystal coating type. The polarizer may also be of a film type or a liquid crystal coating type. The film type polarizer may include a stretchable synthetic resin film, and the liquid crystal-coated type polarizer may include liquid crystals formed in a certain arrangement.

In another aspect, the anti-reflection layer may include a black matrix and color filters. The color filters may be arranged in consideration of the color of light emitted from each light-emitting diode of the display layer 200. In another aspect, the anti-reflection layer may include a destructive interference structure. The destructive interference structure may include a first reflective layer and a second reflective layer arranged on different layers. First reflected light and second reflected light, which are respectively reflected from the first reflective layer and the second reflective layer, may destructively interfere with each other, and thus, the reflectance of external light may be reduced.

The optical function layer 500 may include a lens layer. The lens layer may improve emission efficiency of light emitted from the display layer 200 or reduce color deviation. The lens layer may include a layer having a concave or convex lens shape, or/and may include a plurality of layers having different refractive indices. The optical function layer 500 may include both the anti-reflection layer and the lens layer, or may include one of the anti-reflection layer and the lens layer.

The cover window 600 may be arranged on the optical function layer 500. The cover window 600 may be coupled to the optical function layer 500 through an adhesive layer, such as an optical clear adhesive (OCA), which is arranged between the cover window 600 and the optical function layer 500. The cover window 600 may include a glass material or a plastic material. For example, the cover window 600 may include an ultra-thin glass window. For example, the cover window 600 may include polyethersulfone, polyacrylate, polyether imide, polyethylene naphthalate, polyethylene terephthalate, polyphenylene sulfide, polyarylate, polyimide, polycarbonate, or cellulose acetate propionate.

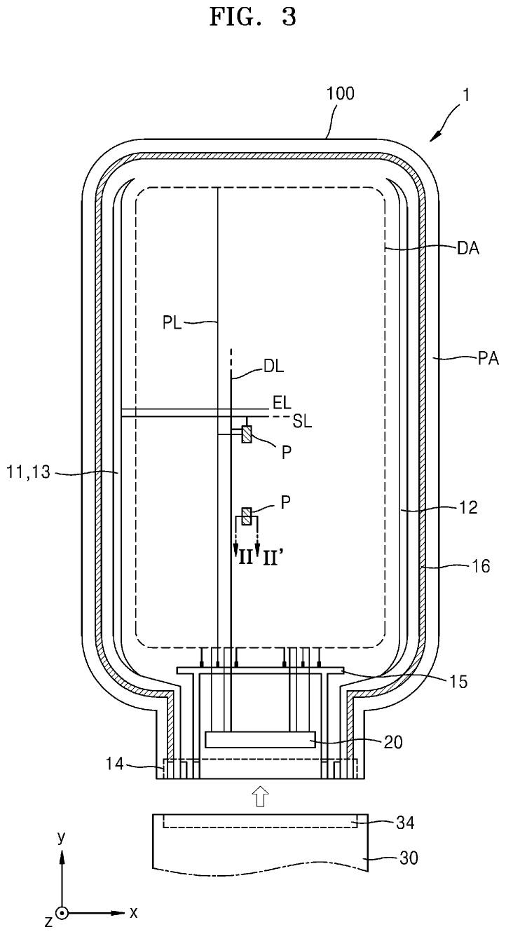

FIG. 3 is a schematic plane view of a display panel according to an aspect.

Referring to FIG. 3, the display panel 10 may include a display area DA and a peripheral area PA outside the display area DA.

The display panel 10 may include a substrate 100. In this specification, in case that the display panel 10 includes the display area DA and the peripheral area PA, it may mean that the substrate 100 includes the display area DA and the peripheral area PA. The substrate 100 may include the display area DA and the peripheral area PA surrounding the display area DA.

The display area DA may be a portion where images are displayed, and a plurality of pixels P may be arranged in the display area DA. In FIG. 3, the display area DA is illustrated as having a rectangular shape with corners rounded, but is not limited thereto. As described above, the display area DA may have various shapes, such as an N-gon (N is a natural number greater than or equal to 3), a circle, or an ellipse.

The peripheral area PA may be arranged outside the display area DA. Peripheral circuits for driving the pixels P may be arranged in the peripheral area PA. For example, in the peripheral area PA may be arranged a first scan driving circuit 11, a second scan driving circuit 12, an emission control driving circuit 13, a terminal 14, a driving power supply line 15, and a common power supply line 16.

The first scan driving circuit 11 may apply a scan signal to the pixel P through a scan line SL. The second scan driving circuit 12 may be arranged parallel to the first scan driving circuit 11 with the display area DA therebetween. Some of the pixels P arranged in the display area DA may be electrically connected to the first scan driving circuit 11, and the rest may be connected to the second scan driving circuit 12. The second scan driving circuit 12 may be omitted if necessary, and all pixels P arranged in the display area DA may be electrically connected to the first scan driving circuit 11.

The emission control driving circuit 13 may be arranged on the side of the first scan driving circuit 11 and may apply an emission control signal to the pixel P through an emission control line EL. In FIG. 3, the emission control driving circuit 13 is illustrated as being arranged only on one side of the display area DA, but may be arranged on opposite sides of the display area DA, like the first scan driving circuit 11 and the second scan driving circuit 12.

A driving chip 20 may be arranged in the peripheral area PA. The driving chip 20 may include an integrated circuit for driving the display panel 10. The integrated circuit may be a data driving integrated circuit which generates a data signal, but the disclosure is not limited thereto.

The terminal 14 may be arranged in the peripheral area PA. The terminal 14 may be exposed without being covered by an insulating layer, to be electrically connected to a printed circuit board 30. The terminal 34 of the printed circuit board 30 may be electrically connected to the terminal 14 of the display panel 10.

The printed circuit board 30 may transmit signals of a control unit (not shown) or power to the display panel 10. A control signal generated in the control unit may be transmitted to each driving circuit through the printed circuit board 30. The control unit may apply a driving voltage ELVDD to the driving power supply line 15 and a common voltage ELVSS to the common power supply line 16. The driving voltage ELVDD may be transmitted to each pixel P through a driving voltage line PL connected to the driving power supply line 15. The driving power supply line 15 may have a shape extending in one direction (e.g., in the x direction) below the display area DA. The common power supply line 16 may have a loop shape with one side open, and may have a shape which partially surrounds the display area DA.

In some aspects, the control unit may generate a data signal, and the generated data signal may be transmitted to an input line IL through the driving chip 20 and then transmitted to the pixel P through a data line DL connected to the input line IL. For reference, the term “line” may refer to a “wiring.” This may also be applied to aspects and modified examples thereof to be described below.

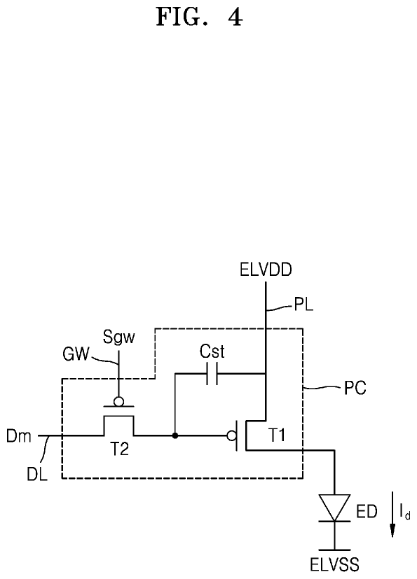

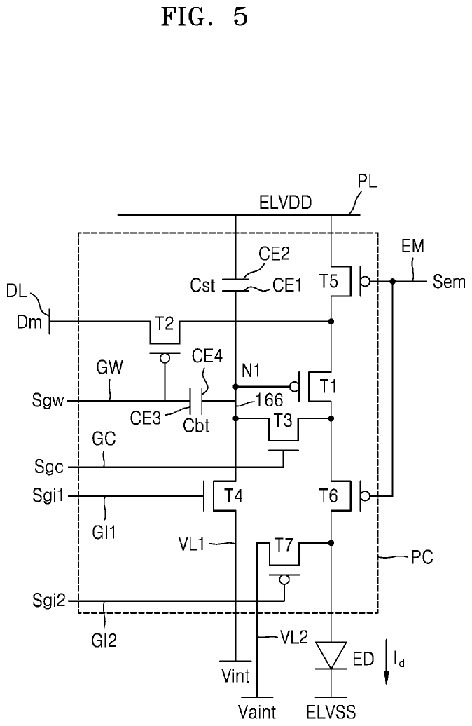

FIGS. 4 and 5 are brief views of equivalent circuits of a pixel included in a display panel according to an aspect.

Referring to FIG. 4, one pixel included in the display panel 10 may include an emission element ED as a display element. The emission element ED may be electrically connected to a pixel circuit PC, and the pixel circuit PC may include a first transistor T1, a second transistor T2, and a storage capacitor Cst.

The second transistor T2 may transmit a data signal Dm, which is input through a data line DL, to the first transistor T1 according to a scan signal Sgw input through a scan line GW.

The storage capacitor Cst may be connected to the second transistor T2 and the driving voltage line PL, and may store a voltage corresponding to a difference between a voltage transmitted from the second transistor T2 and a driving voltage ELVDD applied to the driving voltage line PL.

The first transistor T1 may be connected to the driving voltage line PL and the storage capacitor Cst, and may control a driving current Id, which flows in the emission element ED from the driving voltage line PL, according to a voltage value stored in the storage capacitor Cst. A counter electrode (e.g., a cathode) of the emission element ED may receive a common voltage ELVSS. The emission element ED may emit light with a certain brightness according to the driving current Id.

In FIG. 4, an example in which the pixel circuit PC includes two transistors and one storage capacitor Cst is described, but the disclosure is not limited thereto.

Referring to FIG. 5, the pixel circuit PC may include seven transistors and two capacitors.

The pixel circuit PC may include first to seventh transistors T1, T2, T3, T4, T5, T6, and T7, a storage capacitor Cst, and a boost capacitor Cbt. As another aspect, the pixel circuit PC may not include the boost capacitor Cbt.

Some of the first to seventh transistors T1, T2, T3, T4, T5, T6, and T7 may be n-channel MOSFETs (NMOS), and the rest may be p-channel MOSFETs (PMOS). In another aspect, the third and fourth transistors T3 and T4 may be NMOS and the rest may be PMOS.

The first to seventh transistors T1, T2, T3, T4, T5, T6, and T7, the storage capacitor Cst, and the boost capacitor Cbt may be connected to signal lines. The signal lines may include a scan line GW, an emission control line EM, a compensation gate line GC, a first initialization gate line GI1, a second initialization gate line GI2, and a data line DL. The pixel circuit PC may be electrically connected to voltage lines, for example, a driving voltage line PL, a first initialization voltage line VL1, and a second initialization voltage line VL2.

The first transistor T1 may be a driving transistor. A first gate electrode of the first transistor T1 may be connected to the storage capacitor Cst, a first electrode of the first transistor T1 may be electrically connected to the driving voltage line PL via the fifth transistor T5, and a second electrode of the first transistor T1 may be electrically connected to a pixel electrode (e.g., an anode) of the emission element ED via the sixth transistor T6. One of the first electrode and the second electrode of the first transistor T1 may be a source electrode and the other may be a drain electrode. The first transistor T1 may supply the driving current Id to the emission element ED according to a switching operation of the second transistor T2.

The second transistor T2 may be a switching transistor. A second gate electrode of the second transistor T2 may be connected to the scan line GW, a first electrode of the second transistor T2 may be connected to the data line DL, and a second electrode of the second transistor T2 may be connected to the first electrode of the first transistor T1 and electrically connected to the driving voltage line PL via the fifth transistor T5. One of the first electrode and the second electrode of the second transistor T2 may be a source electrode and the other may be a drain electrode. The second transistor T2 may be turned on according to the scan signal Sgw received through the scan line GW and perform a switching operation to transmit the data signal Dm transmitted through the data line DL to the first electrode of the first transistor T1.

The third transistor T3 may be a compensation transistor to compensate for a threshold voltage of the first transistor T1. A third gate electrode of the third transistor T3 may be connected to a compensation gate line GC. A first electrode of the third transistor T3 may be connected to a lower electrode CE1 of the storage capacitor Cst and the first gate electrode of the first transistor T1 through a node connection line 166. The first electrode of the third transistor T3 may be connected to the fourth transistor T4. A second electrode of the third transistor T3 may be connected to the second electrode of the first transistor T1 and electrically connected to the pixel electrode (e.g., the anode) of the emission element ED via the sixth transistor T6. One of the first electrode and the second electrode of the third transistor T3 may be a source electrode and the other may be a drain electrode.

The third transistor T3 may be turned on according to a compensation signal Sgc received through the compensation gate line GC to electrically connect the first gate electrode and the second electrode (e.g., the drain electrode) of the first transistor T1, thereby diode-connecting the first transistor T1.

The fourth transistor T4 may be a first initialization transistor which initializes the first gate electrode of the first transistor T1. A fourth gate electrode of the fourth transistor T4 may be connected to a first initialization gate line GI1. A first electrode of the fourth transistor T4 may be connected to the first initialization voltage line VL1. A second electrode of the fourth transistor T4 may be connected to the lower electrode CE1 of the storage capacitor Cst, the first electrode of the third transistor T3, and the first gate electrode of the first transistor T1. One of the first electrode and the second electrode of the fourth transistor T4 may be a source electrode and the other may be a drain electrode. The fourth transistor T4 may be turned on according to a first initialization signal Sgi1 received through the first initialization gate line GI1, and transmit a first initialization voltage Vint to the first gate electrode of the first transistor T1 to perform an initialization operation for initializing a voltage of the first gate electrode of the first transistor T1.

The fifth transistor T5 may be an operation control transistor. A fifth gate electrode of the fifth transistor T5 may be connected to an emission control line EM, a first electrode of the fifth transistor T5 may be connected to the driving voltage line PL, and a second electrode of the fifth transistor T5 may be connected to the first electrode of the first transistor T1 and the second electrode of the second transistor T2. One of the first electrode and the second electrode of the fifth transistor T5 may be a source electrode and the other may be a drain electrode.

The sixth transistor T6 may be an emission control transistor. A sixth gate electrode of the sixth transistor T6 may be connected to the emission control line EM, a first electrode of the sixth transistor T6 may be connected to the second electrode of the first transistor T1 and the second electrode of the third transistor T3, and a second electrode of the sixth transistor T6 may be electrically connected to a second electrode of the seventh transistor T7 and the pixel electrode (e.g., the anode) of the emission element ED. One of the first electrode and the second electrode of the sixth transistor T6 may be a source electrode and the other may be a drain electrode.

The fifth transistor T5 and the sixth transistor T6 may be simultaneously turned on according to an emission control signal Sem received through the emission control line EM, so that the driving voltage ELVDD is transmitted to the emission element ED and the driving current Id flows in the emission element ED.

The seventh transistor T7 may be a second initialization transistor which initializes the pixel electrode (e.g., the anode) of the emission element ED. A seventh gate electrode of the seventh transistor T7 may be connected to a second initialization gate line GI2. A first electrode of the seventh transistor T7 may be connected to a second initialization voltage line VL2. A second electrode of the seventh transistor T7 may be connected to the second electrode of the sixth transistor T6 and the pixel electrode (e.g., the anode) of the emission element ED. The seventh transistor T7 may be turned on according to a second initialization signal Sgi2 received through the second initialization gate line GI2, and transmit a second initialization voltage Vaint to the pixel electrode (e.g., the anode) of the emission element ED to initialize the pixel electrode of the emission element ED.

In some aspects, the second initialization gate line GI2 may be a subsequent scan line. For example, the second initialization gate line GI2 connected to the seventh transistor T7 of the pixel circuit PC, which is arranged in an i-th row (i is a natural number), may correspond to a scan line of the pixel circuit PC arranged in a (i+1)-th row. In another aspect, the second initialization gate line GI2 may be the emission control line EM. For example, the emission control line EM may be electrically connected to the fifth to seventh transistors T5, T6, and T7.

The storage capacitor Cst may include a lower electrode CE1 and an upper electrode CE2. The lower electrode CE1 of the storage capacitor Cst may be connected to the first gate electrode of the first transistor T1, and the upper electrode CE2 of the storage capacitor Cst may be connected to the driving voltage line PL. The storage capacitor Cst may store a charge corresponding to a difference between a voltage of the first gate electrode of the first transistor T1 and the driving voltage ELVDD.

The boost capacitor Cbt may include a third electrode CE3 and a fourth electrode CE4. The third electrode CE3 may be connected to the second gate electrode of the second transistor T2 and the scan line GW, and the fourth electrode CE4 may be connected to the first electrode of the third transistor T3 and the node connection line 166. The boost capacitor Cbt may boost a voltage of a first node N1 in case that the scan signal Sgw applied to the scan line GW is turned off, and in case that the voltage of the first node N1 is boosted, a black gray scale may be expressed clearly.

The first node N1 may be an area where the first gate electrode of the first transistor T1, the first electrode of the third transistor T3, the second electrode of the fourth transistor T4, and the fourth electrode CE4 of the boost capacitor Cbt are connected.

The first transistor T1 which directly affects the brightness of the display panel 10 displaying an image may include a semiconductor layer which includes polycrystalline silicon with high reliability, thereby enabling the implementation of a high-resolution display device.

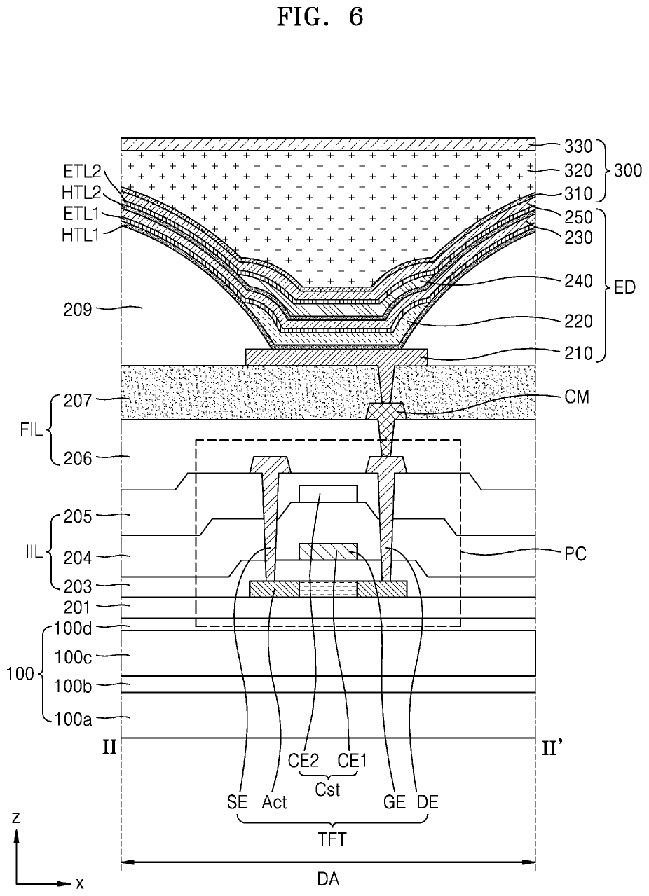

FIG. 6 is a schematic cross-sectional view of an example of a cross-section taken along line II-II′ of FIG. 3.

Referring to FIG. 6, the display panel 10 may include a pixel circuit PC electrically connected to the substrate 100, the emission element ED, and the light-emitting diode ED. In some aspects, the pixel circuit PC and the emission element ED may be arranged on the display area DA of the substrate 100.

The display device 1 may include a substrate 100, a thin-film transistor TFT arranged on the substrate 100, a planarization layer FIL covering the thin-film transistor TFT, and an emission element ED electrically connected to the thin-film transistor TFT on the planarization layer FIL.

The substrate 100 may include an insulating material, such as glass, quartz, or polymer resin. The substrate 100 may be a rigid substrate or a flexible substrate which is bendable, foldable, or rollable. For example, the substrate 100 may include polymer resin, such as polyethersulphone, polyacrylate, polyetherimide, polyethylene napthalate, polyethylene terephthalate, polyphenylene sulfide, polyarylate, polyimide, polycarbonate, or cellulose acetate propionate. The substrate 100 may have a multi-layer structure including a layer including the polymer resin and an inorganic layer (not shown). For example, the substrate 100 may include a first base layer 100a, a first barrier layer 100b, a second base layer 100c, and a second barrier layer 100d, which are sequentially stacked in a thickness direction (e.g., a z-axis direction).

At least one of the first base layer 100a and the second base layer 100c may include the polymer resin. The first barrier layer 100b and the second barrier layer 100d may include an inorganic insulating material, such as silicon nitride, silicon oxide, or silicon oxynitride.

A buffer layer 201 may be arranged on the substrate 100. The buffer layer 201 may reduce or block the penetration of foreign substances, moisture, or external air from the lower portion of the substrate 100, and provide a flat surface on the substrate 100. The buffer layer 201 may include an inorganic material, such as silicon nitride, silicon oxide, or silicon oxynitride, an organic material, or an organic-inorganic composite material, and may have a single-layer or multi-layer structure of inorganic and organic materials.

The pixel circuit PC may be arranged on the buffer layer 201. The pixel circuit PC may include the thin-film transistor TFT and the storage capacitor Cst. The thin-film transistor TFT may include a semiconductor layer Act, a gate electrode GE, a source electrode SE, and a drain electrode DE, and the storage capacitor Cst may include a lower electrode CE1 and an upper electrode CE2.

The semiconductor layer Act may be arranged on the buffer layer 201. The semiconductor layer Act may include polysilicon. In another example, the semiconductor layer Act may include amorphous silicon, an oxide semiconductor, or an organic semiconductor. The semiconductor layer Act may include a channel region, and a drain region and a source region respectively arranged on opposite sides of the channel region.

The gate electrode GE may be arranged on the semiconductor layer Act. The gate electrode GE may overlap the channel region of the semiconductor layer Act. The gate electrode GE may include a low-resistance metal material. The gate electrode GE may include a conductive material, which includes molybdenum (Mo), aluminum (Al), copper (Cu), titanium (Ti), or the like, and may have a single-layer or multi-layer structure including the material.

A first gate insulating layer 203 may be arranged between the semiconductor layer Act and the gate electrode GE. The first gate insulating layer 203 may include an inorganic insulating material, such as silicon oxide, silicon nitride, silicon oxynitride, aluminum oxide, titanium oxide, tantalum oxide, hafnium oxide, or zinc oxide. The first gate insulating layer 203 may have a single-layer or multi-layer structure including the inorganic insulating material.

A second gate insulating layer 204 may be arranged on the gate electrode GE to cover the gate electrode GE. The second gate insulating layer 204 may include an inorganic insulating material, such as silicon oxide, silicon nitride, silicon oxynitride, aluminum oxide, titanium oxide, tantalum oxide, hafnium oxide, or zinc oxide. The second gate insulating layer 204 may have a single-layer or multi-layer structure including the inorganic insulating material.

The upper electrode CE2 of the storage capacitor Cst may be arranged on the second gate insulating layer 204. At least a portion of the upper electrode CE2 may overlap the gate electrode GE, so that the gate electrode GE functions as the lower electrode CE1 of the storage capacitor Cst. For example, the gate electrode GE may be formed integrally with the lower electrode CE1.

The upper electrode CE2 may include a conductive material, which includes molybdenum (Mo), aluminum (Al), copper (Cu), titanium (Ti), or the like, and may have a single-layer or multi-layer structure including the material.

An interlayer insulating layer 205 may be arranged on the upper electrode CE2. The interlayer insulating layer 205 may be formed to cover the upper electrode CE2, and may include silicon oxide, silicon nitride, or silicon oxynitride. The interlayer insulating layer 205 may have a single-layer or multi-layer structure including the inorganic insulating material. An inorganic insulating layer IIL may include the first gate insulating layer 203, the second gate insulating layer 204, and the interlayer insulating layer 205.

The source electrode SE and the drain electrode DE may be arranged on the interlayer insulating layer 205. The source electrode SE and the drain electrode DE may include a conductive material, which includes molybdenum (Mo), aluminum (Al), copper (Cu), titanium (Ti), or the like, and may have a single-layer or multi-layer structure including the material. In an example, the source electrode SE and the drain electrode DE may have a multi-layer structure of Ti/Al/Ti. In some aspects, the source electrode SE or the drain electrode DE may be omitted. For example, adjacent thin-film transistors TFT may share the source region or the drain region of the semiconductor layer Act, and the source region or the drain region may function as the source electrode SE or the drain electrode DE.

A first planarization layer 206 and a second planarization layer 207 may be sequentially arranged to cover the source electrode SE and the drain electrode DE. The first planarization layer 206 and the second planarization layer 207 may have flat upper surfaces so that the pixel electrode 210 arranged thereon is formed flat.

The first planarization layer 206 and the second planarization layer 207 may include general-purpose polymers, such as benzocyclobutene (BCB), polyimide, hexamethyldisiloxane (HMDSO), polymethylmethacrylate (PMMA), or polystyrene (PS), polymer derivatives having phenolic groups, acrylic polymers, imide polymers, aryl ether polymers, amide polymers, fluorinated polymers, p-xylene polymers, or vinyl alcohol polymers. Each of the first planarization layer 206 and the second planarization layer 207 may have a single-layer or multi-layer structure including the organic insulating material. The planarization layer FIL may include the first planarization layer 206 and the second planarization layer 207.

A connection electrode CM may be arranged between the first planarization layer 206 and the second planarization layer 207. The connection electrode CM may be connected to the drain electrode DE of the thin-film transistor TFT through a contact hole, which is defined in the first planarization layer 206. The connection electrode CM may include a conductive material, which includes molybdenum (Mo), aluminum (Al), copper (Cu), titanium (Ti), or the like, and may have a single-layer or multi-layer structure including the material.

In FIG. 6, the planarization layer FIL is shown as having two layers, but the disclosure is not limited thereto. In an aspect, the planarization layer FIL may include only one organic layer. In this case, the connection electrode CM may be omitted, and the pixel electrode 210 of the emission element ED may be directly connected to the drain electrode DE of the thin-film transistor TFT. In another aspect, the planarization layer FIL may include at least three organic layers. In this case, the connection electrode CM may be arranged between adjacent layers of the planarization layer FIL to electrically connect the pixel electrode 210 of the emission element ED and the drain electrode DE of the thin-film transistor TFT.

The emission element ED may be arranged on the planarization layer FIL, for example, the second planarization layer 207. The emission element ED may include a pixel electrode 210, a lower emission layer 220, an intermediate electrode 230, an upper emission layer 240, and a counter electrode 250 which are sequentially stacked on the planarization layer FIL.

The pixel electrode 210 may be arranged on the planarization layer FIL, for example, the second planarization layer 207. The pixel electrode 210 may be electrically connected to the connection electrode CM through a contact hole, which is defined in the second planarization layer 207.

The pixel electrode 210 may include a conductive oxide, such as indium tin oxide (ITO), indium zinc oxide (IZO), zinc oxide (ZnO), indium oxide (In₂O₃), indium gallium oxide (IGO), or aluminum zinc oxide (AZO). The pixel electrode 210 may include a reflective film including silver (Ag), magnesium (Mg), aluminum (Al), platinum (Pt), palladium (Pd), gold (Au), nickel (Ni), neodymium (Nd), iridium (Ir), chromium (Cr), or a compound thereof. For example, the pixel electrode 210 may have a structure with films, which include ITO, IZO, ZnO or In₂O₃, above/below the aforementioned reflective film. In this case, the pixel electrode 210 may have a stacked structure of ITO/Ag/ITO.

The pixel defining layer 209 may be arranged on the planarization layer FIL, for example, the second planarization layer 207, to cover an edge of the pixel electrode 210. The pixel defining layer 209 may have a pixel opening which exposes a center portion of the pixel electrode 210. The pixel opening may define an emission area of the emission element ED, for example, the size and shape of the pixel.

The pixel defining layer 209 may increase a distance between the edge of the pixel electrode 210 and the counter electrode 250 above the pixel electrode 210, thereby suppressing a generation of arcs on the edge of the pixel electrode 210. The pixel defining layer 209 may be formed using an organic insulating material, such as polyimide, polyamide, acrylic resin, benzocyclobutene, hexamethyldisiloxane (HMDSO), and phenol resin, by a method, for example, spin coating.

The pixel defining layer 209 may be black. The pixel defining layer 209 may include a light-shielding material and may be formed as a black layer. The light-shielding material may include resin or paste containing carbon black, carbon nanotubes, or black dye, metal particles, for example, nickel (Ni), aluminum (Al), molybdenum (Mo), and alloys thereof, metal oxide particles (e.g., chromium oxide), or metal nitride particles (e.g., chromium nitride). In case that the pixel defining layer 209 includes a light-shielding material, external reflections due to metal structures arranged below the pixel defining layer 209 may be reduced.

The emission element ED may have a tandem structure, which is a multi-stack structure including a plurality of emission layers. The emission layers 220 and 240 may be arranged to correspond to the pixel opening of the pixel defining layer 209 on the pixel electrode 210. The emission layers 220 and 240 may include a high molecular weight material or a low molecular weight material, and may emit red light, green light, blue light, or white light.

The emission layers 220 and 240 of one emission element ED may emit the same color of light. As an example, the emission layers 220 and 240 of one emission element ED may be red light emission layers which generate red light, green light emission layers which generate green light, or blue light emission layers which generate blue light.

A first hole transport layer HTL1 may be arranged between the lower emission layer 220 and the pixel electrode 210, a first electron transport layer ETL1 may be arranged between the lower emission layer 220 and the intermediate electrode 230, a second hole transport layer HTL2 may be arranged between the intermediate electrode 230 and the upper emission layer 240, and a second electron transport layer ETL2 may be arranged between the upper emission layer 240 and the counter electrode 250.

The first hole transport layer HTL1, the first electron transport layer ETL1, the second hole transport layer HTL2, and the second electron transport layer ETL2 may have a layered structure. The first hole transport layer HTL1 and the first electron transport layer ETL1 may extend beyond the lower emission layer 220. In an area where the lower emission layer 220 is not arranged, the first hole transport layer HTL1 and the first electron transport layer ETL1 may be in direct contact with each other.

The second hole transport layer HTL2 and the second electron transport layer ETL2 may extend beyond the upper emission layer 240. In an area where the upper emission layer 240 is not arranged, the second hole transport layer HTL2 and the second electron transport layer ETL2 may be in direct contact with each other.

The second hole transport layer HTL2 and the second electron transport layer ETL2 may form a layered structure between the intermediate electrode 230 and the counter electrode 250, thereby suppressing a short between the intermediate electrode 230 and the counter electrode 250.

The intermediate electrode 230 may be arranged between the lower emission layer 220 and the upper emission layer 240. Although only two emission layers 220 and 240 are illustrated, the disclosure is not limited thereto, and at least two emission layers may be arranged and the intermediate electrode may further be arranged between the most adjacent emission layers.

The counter electrode 250 may include a conductive material having a relatively low work function. For example, the counter electrode 250 may include a (semi)transparent layer including silver (Ag), magnesium (Mg), aluminum (Al), nickel (Ni), chromium (Cr), lithium (Li), calcium (Ca), or an alloy thereof. In another example, the counter electrode 250 may further include a layer, such as ITO, IZO, ZnO or In₂O₃, on the (semi)transparent layer including the aforementioned material. In an aspect, the counter electrode 250 may include silver (Ag) and magnesium (Mg).

The counter electrode 250 may have a single-layer structure or a multi-layer structure including a plurality of conductive layers. In an aspect, the counter electrode 250 may extend continuously over a plurality of pixels on the display area DA.

Although not shown, in an aspect, a capping layer may be arranged on the counter electrode 250. The capping layer may improve the emission efficiency of the emission element ED by the principle of constructive interference. The capping layer may be an organic capping layer including an organic material, an inorganic capping layer including an inorganic material, or a composite capping layer including an organic material and an inorganic material. For example, the capping layer may include carbocyclic compounds, heterocyclic compounds, amine group-containing compounds, porphine derivatives, phthalocyanine derivatives, naphthalocyanine derivatives, an alkali metal complex, an alkaline earth metal complex, or any combination thereof. The carbocyclic compounds, heterocyclic compounds, and amine group-containing compounds may be optionally substituted with substituents including O, N, S, Se, Si, F, Cl, Br, I, or any combination thereof. In an aspect, the capping layer may include LiF.

A thin-film encapsulation layer 300 which covers the display element, for example, the emission element ED, may be arranged on the counter electrode 250. In an aspect, the thin-film encapsulation layer 300 may include at least one inorganic encapsulation layer and at least one organic encapsulation layer. The thin-film encapsulation layer 300, for example, may include first and second inorganic encapsulation layers 310 and 330, and an organic encapsulation layer 320 arranged between the first and second inorganic encapsulation layers 310 and 330. For example, the thin-film encapsulation layer 300 may include the first inorganic encapsulation layer 310, the organic encapsulation layer 320, and the second inorganic encapsulation layer 330 which are sequentially stacked.

The first and second inorganic encapsulation layers 310 and 330 may each include at least one inorganic insulating material. The inorganic insulating material may include silicon oxide, silicon nitride, or silicon oxynitride. The first and second inorganic encapsulation layers 310 and 330 may be formed by chemical vapor deposition.

The organic encapsulation layer 320 may further include polyethylene terephthalate, polyethylene naphthalate, polycarbonate, polyimide, polyethylene sulfonate, polyoxymethylene, polyarylate, hexamethyldisiloxane, acrylic resin, or a combination thereof. The organic encapsulation layer 320 may provide a flat upper surface. Accordingly, a defect rate may be reduced even in case that the input sensing layer 400 (see FIG. 2) is formed on the display layer 200 (see FIG. 2) through a continuous process.

The thin-film encapsulation layer 300 may be arranged to cover the display area DA and the peripheral area PA. The thin-film encapsulation layer 300 may protect the display element and the like from external foreign substances.

The tandem emission element ED may have a structure in which a plurality of emission layers, for example, at least two emission layers, are stacked between the pixel electrode 210 and the counter electrode 250. To enhance the efficiency of the emission element ED, a charge generation layer which facilitates the generation and movement of charges may be arranged between the emission layers.

To lower a driving voltage, a metal layer TM may be applied between charge generation layers TCGL and BCGL, but a simple metal layer TM may even lead to lateral current leakage issues. Hereinafter, the display device 1, which may reduce a driving voltage while alleviating and suppressing a lateral current leakage problem, will be described in detail.

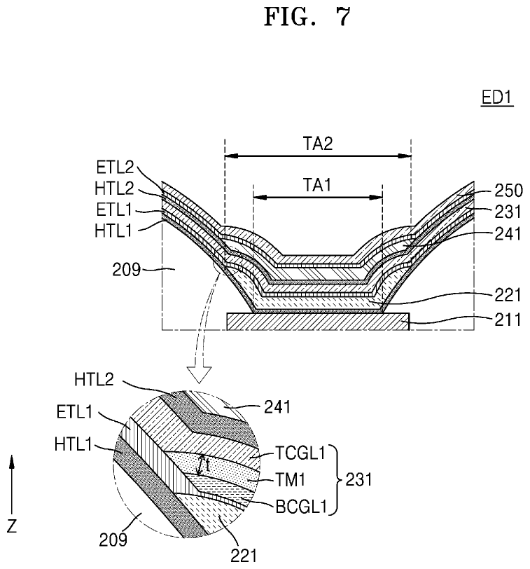

FIG. 7 is a schematic cross-sectional view of an emission element according to an aspect.

Referring to FIG. 7, an emission element ED may include an example of a first emission element ED1, which includes a first pixel electrode 211, a first lower emission layer 221, a first intermediate electrode 231, a first upper emission layer 241, and a counter electrode 250 which are sequentially stacked on a planarization layer FIL in a stacking direction.

The first emission element ED1 may be a tandem emission element including the first lower emission layer 221 and the first upper emission layer 241, and may include the first intermediate electrode 231, which includes a charge generation layer, between the first lower emission layer 221 and the first upper emission layer 241.

The first intermediate electrode 231 may include a first bottom charge generation layer BCGL1 arranged on the first lower emission layer 221, a first top charge generation layer TCGL1 on the first bottom charge generation layer BCGL1, and a first metal layer TM1 between the first bottom charge generation layer BCGL1 and the first top charge generation layer TCGL1.

The first bottom and top charge generation layers BCGL1 and TCGL1 may increase the mobility of electrons toward the first lower emission layer 221 and increase the mobility of holes toward the first upper emission layer 241.

The first bottom and top charge generation layers BCGL1 and TCGL1 may include an n-type charge generation layer n-CGL and a p-type charge generation layer p-CGL. As an example, the first bottom charge generation layer BCGL1 may be the n-type charge generation layer n-CGL, and the first top charge generation layer TCGL1 may be the p-type charge generation layer p-CGL.

As an example, the first bottom charge generation layer BCGL1 and the first top charge generation layer TCGL1 may each extend continuously over a plurality of emission elements ED on the display area DA. For example, the first bottom charge generation layer BCGL1 and the first top charge generation layer TCGL1 may be integrally arranged over the entire display area DA which is also arranged on other emission elements ED in addition to the first emission element ED1.

The first metal layer TM1 may be arranged between the first bottom charge generation layer BCGL1 and the first top charge generation layer TCGL1 to lower a driving voltage. The first metal layer TM1 may control an energy level between the first bottom charge generation layer BCGL1 and the first top charge generation layer TCGL1 to facilitate the movement of holes and electrons. As an example, the first metal layer TM1 may include at least silver (Ag) or gold (Au).

However, in case that the metal layer TM including the first metal layer TM1 is formed integrally even on the other emission elements ED in addition to the first emission element ED1, a lateral current leakage phenomenon may occur in which holes and electrons that should move in the first emission element ED1 move to the other emission elements ED adjacent to the first emission element ED1.

The metal layer TM may alleviate and suppress the lateral current leakage phenomenon by applying a patterned metal layer TM to each emission element ED. For example, the first emission element ED1 may include the first metal layer TM1 having an island shape, patterned in the first emission element ED1.

A thickness t of the first metal layer TM1 may be in the range of 0.1 nm to 10 nm based on a direction in which the first metal layer TM1 is formed. When the thickness t of the first metal layer TM1 is less than 0.1 nm, it may be difficult to form the first metal layer TM1 in a shape with a constant thickness. When the thickness t of the first metal layer TM1 is greater than 10 nm, the reliability of the display device 1 may be deteriorated due to electrical coupling effects with adjacent other structures, and generated light may be difficult to pass through the first metal layer TM1.

The pixel defining layer 209 may be located on the planarization layer FIL and may cover an edge of the first pixel electrode 211 to define the emission area TA1 of the first emission element ED1. Viewed in a stacking direction of the first pixel electrode 211, the first lower emission layer 221, and the first intermediate electrode 231, the first lower emission layer 221 has a plan view area TA2. For example, in plan view, the first lower emission layer 221 has a plan view area TA2. The plan view area TA2 may be larger than the emission area TA1. Further, in plan view, the plan view area TA2 may encompass the emission area TA1. For example, in plan view, the emission area TA1 may be found completely inside the plan view area TA2 of the lower emission layer 221.

The display device 1 may further include a first hole transport layer HTL1 and the first contact area TA1 may be defined where the first pixel electrode 211 and the first hole transport layer HTL1 corresponding to the emission area of the first emission element ED1 are in contact with each other. And the first contact area TA1 may be located in a second contact area TA2 where the first intermediate electrode 231 and the first hole transport layer HTL1 are in contact with each other.

For example, in case of being viewed in the z-axis direction, e.g. in plan view, the plan view area TA2 may be wider than the emission area TA1. In another example, with respect to a plane perpendicular to the z-axis direction, the size of the first metal layer TM1 may be greater than the size of the emission area TA1 of the first emission element ED1 defined by pixel defining layer 209. This may improve power efficiency and reduce a driving voltage when driving the display device 1. In an aspect, the width of the plan view area TA2 may be greater than the width of the emission area TA1 by at least 4 μm.

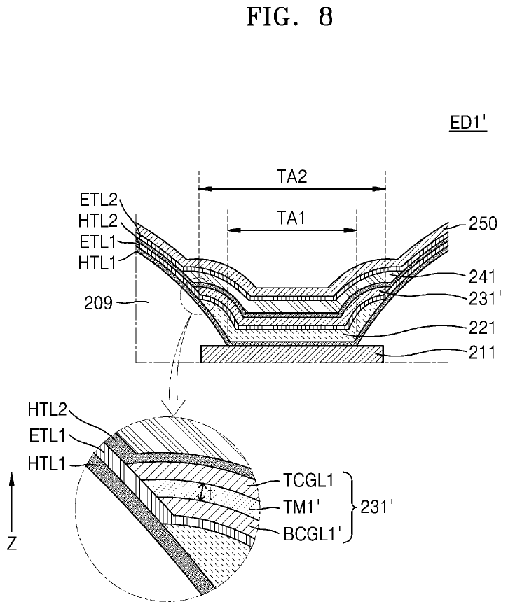

FIG. 8 is a schematic cross-sectional view of an emission element according to another aspect.

Referring to FIG. 8, an emission element ED may include an example of a first emission element ED1′, which includes a first pixel electrode 211, a first lower emission layer 221, a first intermediate electrode 231′, a first upper emission layer 241, and a counter electrode 250 which are sequentially stacked on a planarization layer FIL.

The first emission element ED1′ may be a tandem emission element including the first lower emission layer 221 and the first upper emission layer 241, and may include the first intermediate electrode 231′, which includes a charge generation layer, between the first lower emission layer 221 and the first upper emission layer 241.

The first intermediate electrode 231′ may include a first bottom charge generation layer BCGL1′ arranged on the first lower emission layer 221, a first top charge generation layer TCGL1′ on the first bottom charge generation layer BCGL1′, and a first metal layer TM1′ between the first bottom charge generation layer BCGL1′ and the first top charge generation layer TCGL1′.

The first bottom and top charge generation layers BCGL1′ and TCGL1′ may increase the mobility of electrons toward the first lower emission layer 221 and increase the mobility of holes toward the first upper emission layer 241.

The first bottom and top charge generation layers BCGL1′ and TCGL1′ may include an n-type charge generation layer n-CGL and a p-type charge generation layer p-CGL. As an example, the first bottom charge generation layer BCGL1′ may be the n-type charge generation layer n-CGL, and the first top charge generation layer TCGL1′ may be the p-type charge generation layer p-CGL.

The first metal layer TM1′ may be arranged between the first bottom charge generation layer BCGL1′ and the first top charge generation layer TCGL1′ to lower a driving voltage. The first metal layer TM1′ may control an energy level between the first bottom charge generation layer BCGL1′ and the first top charge generation layer TCGL1′ to facilitate the movement of holes and electrons. As an example, the first metal layer TM1′ may include at least silver (Ag) or gold (Au).

However, in case that a metal layer TM including the first metal layer TM1′ is formed integrally even on other emission elements ED in addition to the first emission element ED1′, a lateral current leakage phenomenon may occur in which holes and electrons that should move in the first emission element ED1′ move to the other emission elements ED adjacent to the first emission element ED1′.

The metal layer TM may alleviate and suppress the lateral current leakage phenomenon by applying a patterned metal layer TM to each emission element ED. For example, the first emission element ED1′ may include the first metal layer TM1′ having an island shape, patterned in the first emission element ED1′.

A thickness t of the first metal layer TM1′ may be in the range of 0.1 nm to 10 nm based on a direction in which the first metal layer TM1′ is formed. When the thickness t of the first metal layer TM1′ is less than 0.1 nm, it may be difficult to form the first metal layer TM1′ in a shape with a constant thickness. When the thickness t of the first metal layer TM1′ is greater than 10 nm, the reliability of the display device 1 may be deteriorated due to electrical coupling effects with adjacent other structures, and generated light may be difficult to pass through the first metal layer TM1′.

In case that the first bottom charge generation layer BCGL1′ and the first top charge generation layer TCGL1′ are formed integrally on the entire emission element ED, a lateral leakage current phenomenon may also occur although it is weaker than that in case of the metal layer TM. To improve this, the bottom charge generation layer BCGL and the top charge generation layer TCGL may be spaced apart from each other between the emission elements ED.

As an example, like the metal layer TM being patterned for each emission element ED, the first bottom charge generation layer BCGL1′ may be a charge generation layer patterned on the first emission element ED1′, and the first top charge generation layer TCGL1′ may also be a charge generation layer patterned on the first emission element ED1′. With the configuration, the lateral current leakage phenomenon between the first emission element ED1′ and a second emission element ED2 may be further alleviated and suppressed.

The pixel defining layer 209 may be located on the planarization layer FIL and may cover an edge of the first pixel electrode 211 to define an emission area TA1 of the first emission element ED1′. Viewed in a stacking direction of the first pixel electrode 211, the first lower emission layer 221, and the first intermediate electrode 231′, the first lower emission layer 221 has a plan view area TA2. For example, in plan view, the first lower emission layer 221 has a plan view area TA2. The plan view area TA2 may be larger than the emission area TA1. Further, in plan view, the plan view area TA2 may encompass the emission area TA1. For example, in plan view, the emission area TA1 may be found completely inside the plan view area TA2 of the lower emission layer 221.

The display device 1 may further include a first hole transport layer HTL1 and the first contact area TA1 may be defined where the first pixel electrode 211 and the first hole transport layer HTL1 corresponding to the emission area of the first emission element ED1′ are in contact with each other. And the first contact area TA1 may be located in a second contact area TA2 where the first intermediate electrode 231′ and the first hole transport layer HTL1 are in contact with each other.

For example, in case of being viewed in the z-axis direction, e.g. in plan view, the plan view area TA2 may be wider than the emission area TA1. In another example, with respect to a plane perpendicular to the z-axis direction, the size of the first metal layer TM1′ may be greater than the size of the emission area TA1. This may improve power efficiency and reduce a driving voltage when driving the display device 1. In an aspect, the width of the plan view area TA2 may be greater than the width of the emission area TA1 by at least 4 μm.

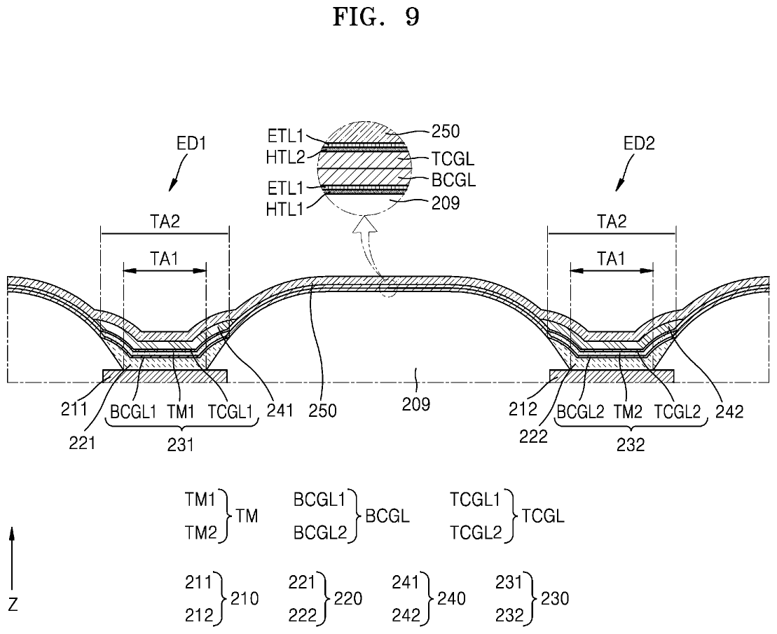

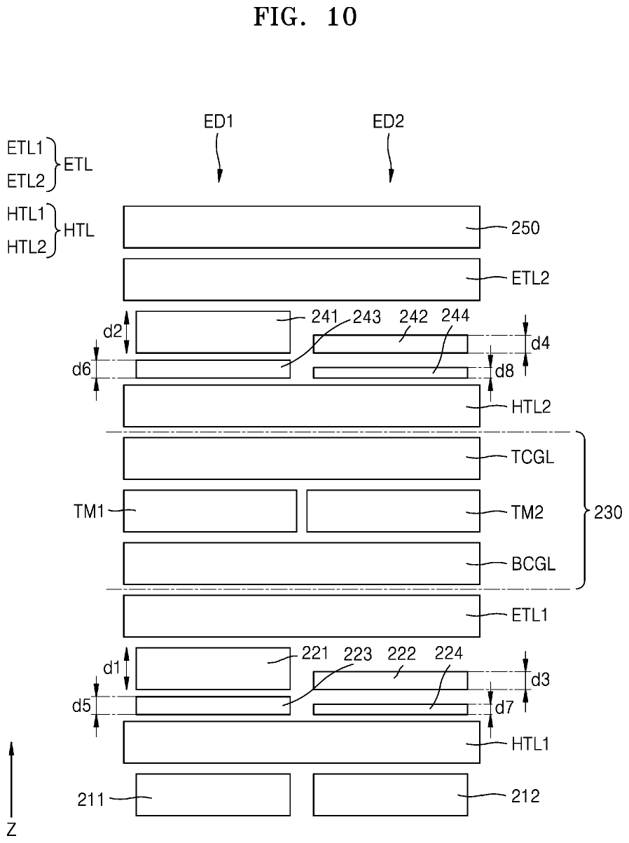

FIG. 9 is a schematic cross-sectional view of two adjacent emission elements according to an aspect. FIG. 10 is a schematic cross-sectional view of layers of the emission elements shown in FIG. 9.

Referring to FIGS. 9 and 10, the display device 1 according to an example may further include a second emission element ED2 which is adjacent to the first emission element ED1, and electrically connected to a thin-film transistor TFT, which is different from a thin-film transistor TFT electrically connected to the first emission element ED1.

The second emission element ED2 may include a second pixel electrode 212, a second lower emission layer 222, a second intermediate electrode 232, a second upper emission layer 242, and a counter electrode 250 which are sequentially stacked on the planarization layer FIL.

For example, a first hole transport layer HTL1 may be arranged between the lower emission layer 220 and the pixel electrode 210, a first electron transport layer ETL1 may be arranged between the lower emission layer 220 and the intermediate electrode 230, a second hole transport layer HTL2 may be arranged between the intermediate electrode 230 and the upper emission layer 240, and a second electron transport layer ETL2 may be arranged between the upper emission layer 240 and the counter electrode 250.

The first hole transport layer HTL1 may control an energy level of an interface to facilitate smooth generation and movement of charges to the lower emission layer 220. The first electron transport layer ETL1 may transfer electrons to the lower emission layer 220. The second hole transport layer HTL2 may transfer holes to the upper emission layer 240. The second electron transport layer ETL2 may transfer electrons to the upper emission layer 240.

The first hole transport layer HTL1, the first electron transport layer ETL1, the second hole transport layer HTL2, and the second electron transport layer ETL2 may be an integral single layer which is arranged over all the emission elements ED.

The second intermediate electrode 232 may include a second bottom charge generation layer BCGL2 arranged on the second pixel electrode 212, a second top charge generation layer TCGL2 on the second bottom charge generation layer BCGL2, and a second metal layer TM2 between the second bottom charge generation layer BCGL2 and the second top charge generation layer TCGL2.

The second metal layer TM2 may be spaced apart from the first metal layer TM1 and thus the second metal layer TM2 and the first metal layer TM1 may each have an island shape. Accordingly, a movement path of holes or electrons between the second metal layer TM2 and the first metal layer TM1 may be eliminated, thereby improving a phenomenon in which the second emission element ED2 adjacent to the first emission element ED1 is driven by leakage current while driving the first emission element ED1.

The first emission element ED1 and the second emission element ED2 may be emission elements ED which emit different colors of light, as an example. In this case, it may be possible to improve a color mixing problem, which is caused, while driving an emission element emitting a certain color of light, due to an adjacent emission element emitting a different color of light being driven due to leakage current.

The first emission element ED1 and the second emission element ED2 may be emission elements ED which emit the same color of light, as another example. In this case, the same current may flow in each emission element ED even though the emission elements ED emit the same color of light, thereby reducing stain in the display area DA and enhancing display quality of the display device 1.

The second metal layer TM2 may be spaced apart from the first metal layer TM1 to alleviate and suppress the lateral current leakage, and thus the first bottom charge generation layer BCGL1 and the second bottom charge generation layer BCGL2 may be integral with each other. The first top charge generation layer TCGL1 and the second top charge generation layer TCGL2 may also be integral with each other.

In areas except for the emission element ED, the bottom charge generation layer BCGL and the top charge generation layer TCGL may be in contact with each other.

In case where the first emission element ED1 and the second emission element ED2 emit different colors of light, resonance may be controlled by adjusting the thicknesses of the lower emission layer 220 and the upper emission layer 240. As an example, in case of an emission element which emits red light, the red light may have a long wavelength and thus the emission element may be stacked with a great thickness, while in case of an emission element which emits green light with a shorter wavelength than the red light, the emission element may be stacked with a relatively small thickness.

In case where the first emission element ED1 and the second emission element ED2 emit different colors of light, a thickness d1 of the first lower emission layer 221 may be different from a thickness d3 of the second lower emission layer 222. For example, in case where the first emission element ED1 emits red light and the second emission element ED2 emits green light, the thickness d1 of the first lower emission layer 221 may be greater than the thickness d3 of the second lower emission layer 222.

In case where the first emission element ED1 and the second emission element ED2 emit different colors of light, a thickness d2 of the first upper emission layer 241 may be different from a thickness d4 of the second upper emission layer 242. For example, in case where the first emission element ED1 emits red light and the second emission element ED2 emits green light, the thickness d2 of the first upper emission layer 241 may be greater than the thickness d4 of the second upper emission layer 242.

In case where the thickness d1 of the first lower emission layer 221 is greater than the thickness d3 of the second lower emission layer 222, the thickness d2 of the first upper emission layer 241 may also be greater than the thickness d4 of the second upper emission layer 242. In case where the thickness d1 of the first lower emission layer 221 is smaller than the thickness d3 of the second lower emission layer 222, the thickness d2 of the first upper emission layer 241 may also be smaller than the thickness d4 of the second upper emission layer 242.

Step compensation layers 223, 224, 243, and 244 (see FIG. 10), which are layers for controlling resonance, may be arranged below the corresponding emission layers 221, 222, 241, and 242. The step compensation layers 223, 224, 243, and 244 below the corresponding emission layers 221, 222, 241, and 242 may be used to adjust the thickness according to the colors of light emitted by the emission layers 221, 222, 241, and 242, and may include the same material as the emission layers 221, 222, 241, and 242.

In an aspect, the first emission element ED1 may further include a first lower step compensation layer 223 located between the first pixel electrode 211 and the first lower emission layer 221, and the second emission element ED2 may further include a second lower step compensation layer 224 located between the second pixel electrode 212 and the second lower emission layer 222.

In case where the first emission element ED1 and the second emission element ED2 emit different colors of light, a thickness d5 of the first lower step compensation layer 223 may be different from a thickness d7 of the second lower step compensation layer 224.

In an aspect, the first emission element ED1 may further include a first upper step compensation layer 243 located between the first intermediate electrode 231 and the first upper emission layer 241, and the second emission element ED2 may further include a second upper step compensation layer 244 located between the second intermediate electrode 232 and the second upper emission layer 242.

In case where the first emission element ED1 and the second emission element ED2 emit different colors of light, a thickness d6 of the first upper step compensation layer 243 may be different from a thickness d8 of the second upper step compensation layer 244.

As an example, red light may have a long wavelength. Therefore, a step compensation layer below an emission element which emits the red light may have a great thickness, and a step compensation layer below an emission element emitting green light, which has a relatively shorter wavelength than the red light, may have a relatively small thickness.

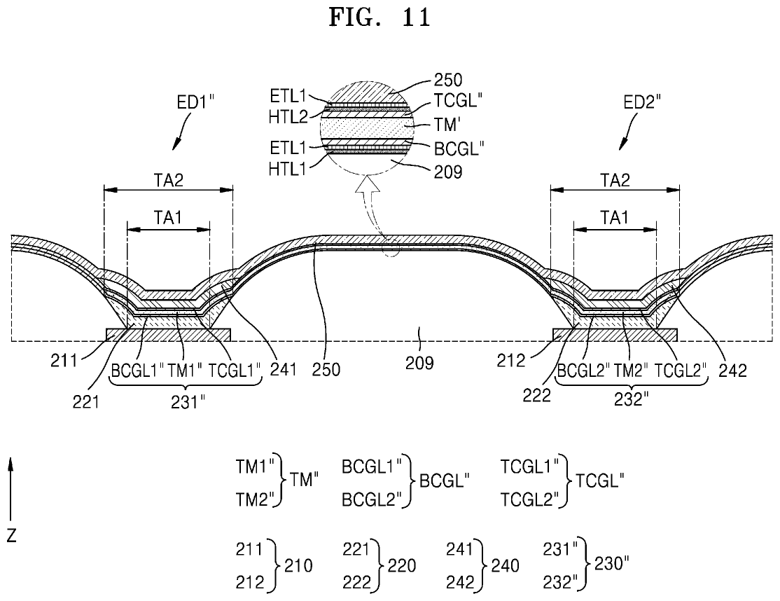

FIG. 11 is a schematic cross-sectional view of two adjacent emission elements according to another aspect.

Referring to FIG. 11, another example of the display device 1 may further include a second emission element ED2″ electrically connected to a thin-film transistor TFT different from a thin-film transistor TFT, which is electrically connected to a first emission element ED1″, and arranged adjacent to the first emission element ED1″.

The second emission element ED2″ may include a second pixel electrode 212, a second lower emission layer 222, a second intermediate electrode 232″, a second upper emission layer 242, and a counter electrode 250 which are sequentially stacked on a planarization layer FIL.

The second intermediate electrode 232″ may include a second bottom charge generation layer BCGL2″ arranged on the second pixel electrode 212, a second top charge generation layer TCGL2″ on the second bottom charge generation layer BCGL2″, and a second metal layer TM2″ between the second bottom charge generation layer BCGL2″ and the second top charge generation layer TCGL2″.

As an example, the first metal layer TM1″ and the second metal layer TM2″ may be integral with each other. In case where the first emission element ED1″ and the second emission element ED2″ adjacent to the first emission element ED1″ emit the same color of light, a screen stain phenomenon caused by lateral leakage current may not be a significant problem even though the first metal layer TM1″ and the second metal layer TM2″ are integral with each other.

The first metal layer TM1″ and the second metal layer TM2″ may be formed as independently separated island patterns (islands) on the same plane (see FIG. 9). When the first emission element ED1″ and the second emission element ED2″ are arranged adjacent to each other, the adjacent ends of the first metal layer TM1″ and the second metal layer TM2″ may be connected to form a continuous structure (see FIG. 11). That is, although the first metal layer TM1″ and the second metal layer TM2″ belong to different pixels, they may be connected to each other at the connecting region to form an integrated structure.

The first bottom charge generation layer BCGL1″ and the second bottom charge generation layer BCGL2″ may also be integral with each other. The first top charge generation layer TCGL1″ and the second top charge generation layer TCGL2″ may also be integral with each other. In areas except for the first emission element ED1″ and the second emission element ED2″, the bottom charge generation layer BCGL″ and the top charge generation layer TCGL″ may be in contact with each other.

To the extent that it does not conflict with the description according to FIG. 11, the components of the display device 1 described in FIGS. 9 and 10 and the corresponding effects may also be applied to the display device 1 described in FIG. 11.

The display device 1 according to an aspect may be applied to various electronic devices 1000. An electronic device 1000 according to an aspect may include the display device 1 described above, and may further include a module or device having additional functions in addition to the display device 1.

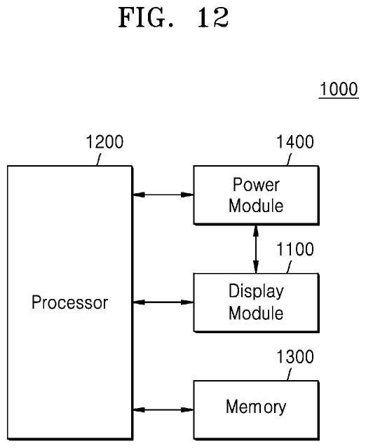

FIG. 12 is a block diagram of an electronic device according to aspect. Referring to FIG. 12, an electronic device 1000 according to an aspect may include a display module 1100, a processor 1200, a memory 1300, and a power module 1400.

The processor 1200 may include at least one of a central processing unit (CPU), an application processor (AP), a graphic processing unit (GPU), a communication processor CP, an image signal processor (ISP), or a controller.

The memory 1300 may store data information which is required for the operation of the processor 1200 or the display module 1100. In case that the processor 1200 executes an application stored in the memory 1300, an image data signal and/or an input control signal may be transmitted to the display module 1100, and the display module 1100 may process the received signal and output image information through a display screen.

The power module 1400 may include a power supply module, such as a power adapter or a battery device, and a power conversion module which converts power supplied by the power supply module to generate power required for the operation of the electronic device 1000.

At least one of the components of the electronic device 1000 may be included in the display device 1 according to the foregoing aspects. Some of individual modules functionally included in a single module may be included in the display device and others may be provided separately from the display device. For example, the display device 1 may include the display module 1100, and the processor 1200, the memory 1300, and the power module 1400 may be provided as other devices inside the electronic device 1000 other than the display device 1.

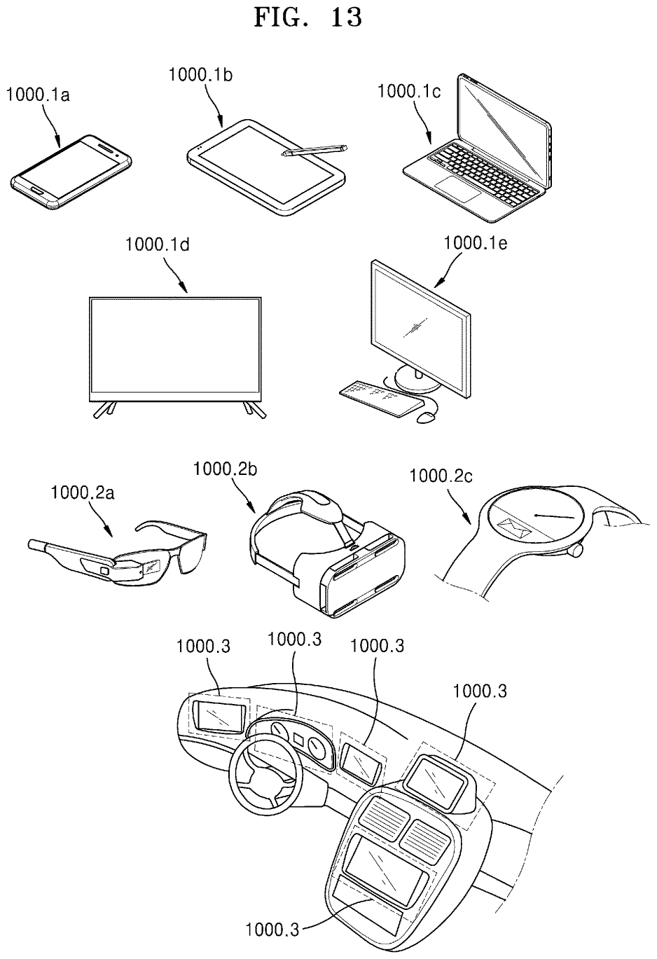

FIG. 13 is a variety of schematic views of an electronic device according to various aspects.

Referring to FIG. 13, various electronic devices according to aspects to which the display device 1 is applied may include image display electronic devices, such as a smart phone 1000.1a, a tablet PC 1000.1b, a laptop 1000.1c, a TV 1000.1d, and a desk monitor 1000.1e, wearable electronic devices including display modules, such as smart glasses 1000.2a, a head mounted display 1000.2b, and a smart watch 1000.2c, and vehicle electronic devices 1000.3 including display modules, such as a dashboard of an automobile, center fascia, a center information display (CID) arranged on the dashboard, and a room mirror display.

According to one or more aspects, a display device with improved screen quality and reliability, and an electronic device including the same may be provided.

However, the effects obtainable through the disclosure are not limited to the effects described above, and other technical effects not mentioned will be clearly understood by those skilled in the art from the description of the disclosure described above.

Each of the aspects described above may be implemented independently, but of course, the structure of each aspect may be applied in combination to other aspects.

As such, the disclosure has been described with reference to the aspects illustrated in the drawings, but is merely illustrative, and it will be understood by those skilled in the art that various modifications and variations of the aspects may be made.

The specific executions described in the aspects are merely illustrative, and do not limit the scope of the disclosure in any way. Furthermore, unless otherwise indicated obviously by terms, such as “essential”, “important”, and the like, a component may not be a necessary component for the application of the disclosure.

In the specification of the aspect, the use of the term “the” and similar referential terms may refer to both the singular and the plural. In case that a range is described in the aspects, it includes the invention to which individual values within the range are applied (unless otherwise indicated herein). This is the same as stating each individual value constituting the above range in the detailed description. Finally, operations constituting methods according to aspects may be performed in any suitable order unless otherwise indicated herein or otherwise clearly contradicted by context. The aspects are not necessarily limited by the order of description of operations. The use of any and all examples or exemplary terms provided in the aspects is simply intended to describe the aspects in detail, and the scope of the aspects is not limited by the examples or exemplary terms unless otherwise claimed. Further, it will be understood by those skilled in the art that various modifications, combinations and changes may be made depending on design conditions and factors within the scope of the disclosure.

What is claimed is:

1. A display device comprising:
a substrate;
a thin-film transistor arranged on the substrate;
a planarization layer covering the thin-film transistor;
a first emission element electrically connected to the thin-film transistor, the first emission element comprising a first pixel electrode, a first lower emission layer, a first intermediate electrode, a first upper emission layer, and a counter electrode sequentially stacked on the planarization layer; and
a pixel defining layer located on the planarization layer, the pixel defining layer covering an edge of the first pixel electrode to define an emission area of the first emission element in a plan view,
wherein, in the plan view, the first lower emission layer has an plan view area, and in the plan view, the emission area is located in the plan view area of the first lower emission layer.

2. The display device of claim 1, wherein
the first intermediate electrode comprises a first bottom charge generation layer, a first top charge generation layer, and a first metal layer between the first bottom charge generation layer and the first top charge generation layer.

3. The display device of claim 2, wherein
the first metal layer has a thickness in a range of 0.1 nm to 10 nm.

4. The display device of claim 2, further comprising
a second emission element electrically connected to a second thin-film transistor arranged on the substrate, the second emission element comprising a second pixel electrode, a second lower emission layer, a second intermediate electrode, a second upper emission layer, and the counter electrode sequentially stacked on the planarization layer,
wherein the second intermediate electrode comprises a second bottom charge generation layer, a second top charge generation layer, and a second metal layer between the second bottom charge generation layer and the second top charge generation layer, and
the first metal layer and the second metal layer each have an island shape by being spaced apart from each other.

5. The display device of claim 4, wherein
the first bottom charge generation layer and the second bottom charge generation layer are integral with each other.

6. The display device of claim 4, wherein
the first top charge generation layer and the second top charge generation layer are integral with each other.

7. The display device of claim 4, wherein
the first emission element and the second emission element are arranged adjacent to each other, and
the first metal layer and the second metal layer are integral with each other.

8. The display device of claim 4, wherein
a thickness of the first lower emission layer is different from a thickness of the second lower emission layer, and a thickness of the first upper emission layer is different from a thickness of the second upper emission layer.

9. The display device of claim 4, wherein
the first emission element further comprises a first lower step compensation layer located between the first pixel electrode and the first lower emission layer, and
the second emission element further comprises a second lower step compensation layer located between the second pixel electrode and the second lower emission layer, the second lower step compensation layer having a different thickness from the first lower step compensation layer.

10. The display device of claim 4, wherein
the first emission element further comprises a first upper step compensation layer located between the first intermediate electrode and the first upper emission layer, and
the second emission element further comprises a second upper step compensation layer located between the second intermediate electrode and the second upper emission layer, the second upper step compensation layer having a different thickness from the first upper step compensation layer.

11. A display device comprising:
a substrate;
a first and a second thin-film transistors arranged on the substrate;
a planarization layer covering the first and the second thin-film transistors;
a first emission element electrically connected to the first thin-film transistor, the first emission element comprising a first pixel electrode, a first lower emission layer, a first intermediate electrode, a first upper emission layer, and a counter electrode sequentially stacked on the planarization layer; and
a second emission element electrically connected to the second thin-film transistor, the second emission element comprising a second pixel electrode, a second lower emission layer, a second intermediate electrode, a second upper emission layer, and the counter electrode sequentially stacked on the planarization layer,
wherein the first intermediate electrode comprises a first bottom charge generation layer, a first top charge generation layer, and a first metal layer between the first bottom charge generation layer and the first top charge generation layer,
the second intermediate electrode comprises a second bottom charge generation layer, a second top charge generation layer, and a second metal layer between the second bottom charge generation layer and the second top charge generation layer, and
the first metal layer and the second metal layer each have an island shape by being spaced apart from each other.

12. The display device of claim 11, wherein
a thickness of the first metal layer and a thickness of the second metal layer are each in a range of 0.1 nm to 10 nm.

13. The display device of claim 11, further comprising
a pixel defining layer located on the planarization layer, the pixel defining layer defining an emission area of the first emission element by covering an edge of the first pixel electrode and an emission area of the second emission element by covering an edge of the second pixel electrode,
wherein, in the plan view, the first lower emission layer has an plan view area, and in the plan view, the emission area of the first emission element is located in the plan view area of the first lower emission layer.

14. The display device of claim 11, wherein
the first bottom charge generation layer and the second bottom charge generation layer are integral with each other.

15. The display device of claim 11, wherein
the first top charge generation layer and the second top charge generation layer are integral with each other.

16. The display device of claim 11, wherein
the first emission element and the second emission element are arranged adjacent to each other, and
the first metal layer and the second metal layer are integral with each other.

17. The display device of claim 11, wherein
a thickness of the first lower emission layer is different from a thickness of the second lower emission layer, and a thickness of the first upper emission layer is different from a thickness of the second upper emission layer.

18. The display device of claim 11, wherein
the first emission element further comprises a first lower step compensation layer located between the first pixel electrode and the first lower emission layer, and
the second emission element further comprises a second lower step compensation layer located between the second pixel electrode and the second lower emission layer, the second lower step compensation layer having a different thickness from the first lower step compensation layer.

19. The display device of claim 11, wherein
the first emission element further comprises a first upper step compensation layer located between the first intermediate electrode and the first upper emission layer, and
the second emission element further comprises a second upper step compensation layer located between the second intermediate electrode and the second upper emission layer, the second upper step compensation layer having a different thickness from the first upper step compensation layer.

20. An electronic device comprising a display device,
wherein the display device comprises:
a substrate;
a thin-film transistor arranged on the substrate;
a planarization layer covering the thin-film transistor;
a first emission element electrically connected to the thin-film transistor, the first emission element comprising a first pixel electrode, a first lower emission layer, a first intermediate electrode, a first upper emission layer, and a counter electrode sequentially stacked on the planarization layer; and
a pixel defining layer located on the planarization layer, the pixel defining layer covering an edge of the first pixel electrode to define an emission area of the first emission element in a plan view, and
in the plan view, the first lower emission layer has an plan view area, and in the plan view, the emission area is located in the plan view area of the first lower emission layer.
